(19) United States
(12) Patent Application Publication
(10) Pub. No.: US 2025/0204225 A1
(43) Pub. Date: Jun. 19, 2025

(54) DISPLAY APPARATUS

(71) Applicant: LG Display Co., Ltd., Seoul (KR)

(72) Inventors: Donggu Kim, Paju-si (KR); Hyemin Park, Paju-si (KR); Inae Choi, Paju-si (KR); Sejong Seong, Paju-si (KR)

(73) Assignee: LG Display Co., Ltd., Seoul (KR)

(21) Appl. No.: 18/921,945

(22) Filed: Oct. 21, 2024

(30) Foreign Application Priority Data
Dec. 19, 2023 (KR) 10-2023-0186316

(51) Int. Cl. H10K 59/80; H10K 59/124

(52) U.S. Cl. CPC H10K 59/878; H10K 59/124; H10K 59/80518; H10K 59/879

(57) ABSTRACT

A display apparatus for improving a light extraction efficiency of light emitted from a light emitting layer is provided. The display apparatus may include a substrate including a plurality of the pixels having a plurality of the sub-pixels; a pattern portion disposed on the substrate to be concave in a non-light emission area between the plurality of the sub-pixels; a reflective portion disposed on the pattern portion; and a light rerouting layer disposed below the reflective portion in the pattern portion.

### CROSS-REFERENCE TO RELATED APPLICATIONS

This application claims the benefit of Korean Patent Application No. 10-2023-0186316, filed on Dec. 19, 2023, which is hereby incorporated by reference as if fully set forth herein.

### BACKGROUND

### Field of the Invention

The present disclosure relates to a display apparatus.

### Discussion of the Related Art

Since an organic light emitting display apparatus has a high response speed and low power consumption and self-emits light without requiring a separate light source unlike a liquid crystal display apparatus, there is no problem in a viewing angle and thus the organic light emitting display apparatus has received attention as a next-generation flat panel display apparatus.

Such a display apparatus displays an image through light emission of a light emitting element layer that includes a light emitting layer interposed between two electrodes.

Meanwhile, light extraction efficiency of the display apparatus is reduced as some of light emitted from the light emitting element layer is not emitted to the outside due to total reflection on the interface between multiple layers inside a display panel.

### SUMMARY

Accordingly, the present disclosure is directed to a display apparatus that substantially obviates one or more of the problems due to limitations and disadvantages of the related art.

An aspect of the present disclosure is directed to providing a display apparatus of which the light extraction efficiency of light emitted from light emitting layer may be improved.

An aspect of the present disclosure is directed to providing a display apparatus which may reduce the overall power consumption by light extraction from a non-emission area.

An aspect of the present disclosure is directed to providing a display apparatus of which a short-circuit of reflecting electrode may be prevented.

An aspect of the present disclosure is directed to providing a display apparatus which may maximize light extraction efficiency.

The objects of the present disclosure are not limited to the above-described objects, and other objects not mentioned can be clearly understood by those skilled in the art from the following description.

To achieve these objects and other advantages of the present disclosure, as embodied and broadly described herein, a display apparatus according to an embodiment of the present disclosure may include a substrate including a plurality of the pixels having a plurality of the sub-pixels; a pattern portion disposed on the substrate to be concave in a non-light emission area between the plurality of the sub-pixels; a reflective portion disposed on the pattern portion; and a light rerouting layer disposed below the reflective portion in the pattern portion.

To achieve these objects and other advantages of the present disclosure, as embodied and broadly described herein, a display apparatus according to another embodiment of the present disclosure may include a substrate including a plurality of the pixels having a plurality of the sub-pixels; an overcoat layer disposed on the substrate; a pattern portion disposed in the overcoat layer to be concave in a non-light emission area between the plurality of the sub-pixels; and a light rerouting layer disposed in the pattern portion. Wherein, a refractive index of the light rerouting layer is smaller than a refractive index of the overcoat layer.

The advantages and effects according to the present disclosure are not limited to those described above, and additional advantages and effects are included in or may be obtained from the present disclosure.

Additional features and aspects of the disclosure will be set forth in the description that follows and in part will become apparent from the description or may be learned by practice of the inventive concepts provided herein. Other features and aspects of the inventive concepts may be realized and attained by the structure particularly pointed out in, or derivable from, the written description, claims hereof, and the appended drawings.

It is to be understood that both the foregoing general description and the following detailed description of the present disclosure are by way of example and are intended to provide further explanation of the disclosures as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principles of the disclosure.

FIG. 1 is a schematic plan view of a display apparatus according to an example embodiment of the present disclosure.

FIG. 2 is a schematic plan view of one example pixel illustrated in FIG. 1.

FIG. 3 is an example schematic cross-sectional view taken along a line I-I′ illustrated in FIG. 2.

FIG. 4 is an example schematic cross-sectional view taken along a line II-II′ illustrated in FIG. 2.

FIG. 5 is an example schematic cross-sectional view taken along a line III-III′ illustrated in FIG. 2.

FIG. 6 is an example schematic enlarged cross-sectional view of portion A illustrated in FIG. 3.

FIG. 7 is a schematic enlarged cross-sectional view illustrating a display apparatus according to another example embodiment of the present disclosure, as another example of the portion A illustrated in FIG. 3.

### DETAILED DESCRIPTION

Reference will now be made in detail to the embodiments of the present disclosure, examples of which are illustrated in the accompanying drawings. Wherever possible, the same reference numbers will be used throughout the drawings to refer to the same or like parts.

Advantages and features of the present disclosure and methods of achieving them will become apparent with reference to the example embodiments described below in detail in conjunction with the accompanying drawings. The present disclosure may, however, be embodied in different forms and should not be construed as limited to the example embodiments set forth herein. Rather, these example embodiments are provided so that this disclosure will be thorough and complete and will fully convey the scope of the present disclosure to those skilled in the art.

The shapes, dimensions, areas, lengths, thicknesses, ratios, angles, numbers, and the like, which are illustrated in the drawings to describe various example embodiments of the present disclosure, are merely given by way of example. Therefore, the present disclosure is not limited to such illustrated details in the drawings. Like reference numerals generally denote like elements throughout the specification, unless otherwise specified.

In the following description, where a detailed description of a relevant known function or configuration may unnecessarily obscure aspects of the present disclosure, a detailed description of such a known function or configuration may be omitted or be briefly discussed.

Where a term like “comprise,” “have,” or “include” is used, one or more other elements may be added unless the term is used with a more limiting term, such as “only” or the like. An element described in a singular form may include a plurality of elements, and vice versa, unless the context clearly indicates otherwise.

In construing an element, the element should be construed as including an error or tolerance range even where no explicit description of such an error or tolerance range is provided.

Where a positional relationship between two elements is described with such a term as “on,” “above,” “under,” “next to,” or the like, one or more other elements may be located between the two elements unless the term is used with a more limiting term, such as “immediate (ly)” or “direct (ly).”

Where a temporal relationship is described using such a term as “after,” “subsequent (ly),” “next,” “before,” or the like, it may include a non-consecutive or non-continuous case unless it is used with a more limiting term like “immediately” or “directly.”

Although terms “first,” “second,” and the like may be used herein to describe various elements, these elements should not be interpreted to be limited by these terms as they are not used to define a particular essence, order, sequence, precedence, or number of such elements. These terms are used only to refer one element separately from another. For example, a first element could be termed a second element, and a second element could similarly be termed a first element, without departing from the scope of the present disclosure.

Terms like “X-axis direction,” “Y-axis direction,” and “Z-axis direction” should not be construed by a geometric relation only of a mutual vertical relation and may have broader directionality within the range that elements of the present disclosure may act functionally.

The term “at least one” should be understood as including any and all combinations of one or more of the associated listed items. For example, the meaning of “at least one of a first item, a second item, and a third item” denotes the combination of all items proposed from two or more of the first item, the second item and the third item as well as the first item, the second item or the third item.

Features of various embodiments of the present disclosure may be partially or wholly coupled to or combined with each other, and may be operated, linked, or driven together in various ways as those skilled in the art can sufficiently understand. The embodiments of the present disclosure may be carried out independently from each other, or may be carried out together in association with each other.

Hereinafter, example embodiments of the present disclosure will be described in detail with reference to the accompanying drawings.

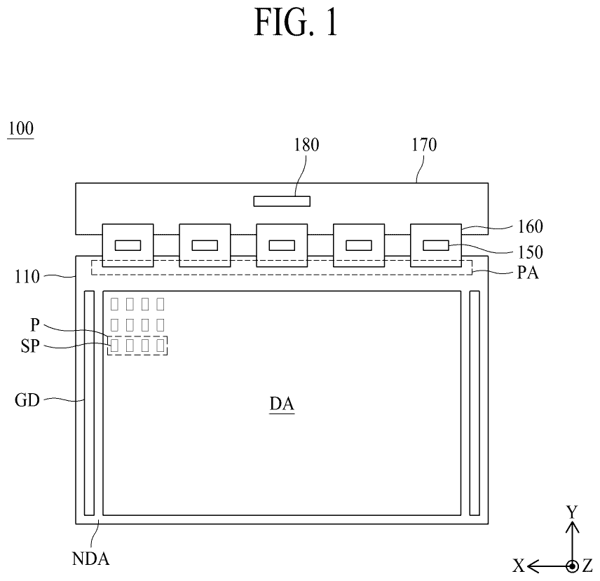

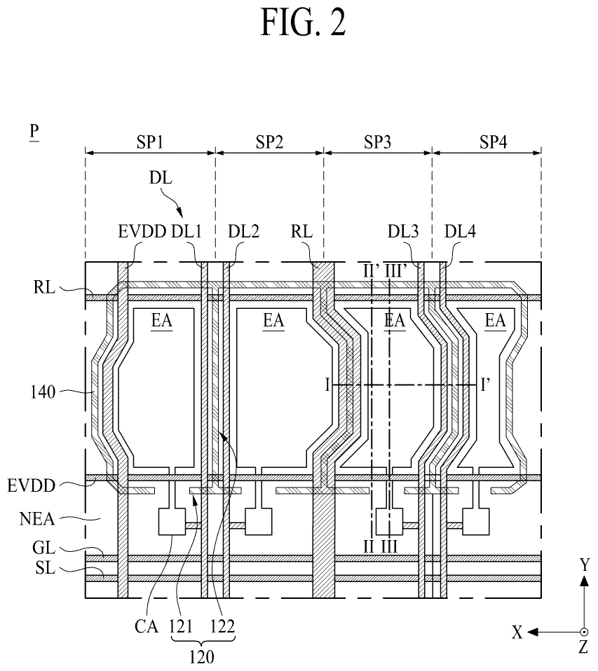

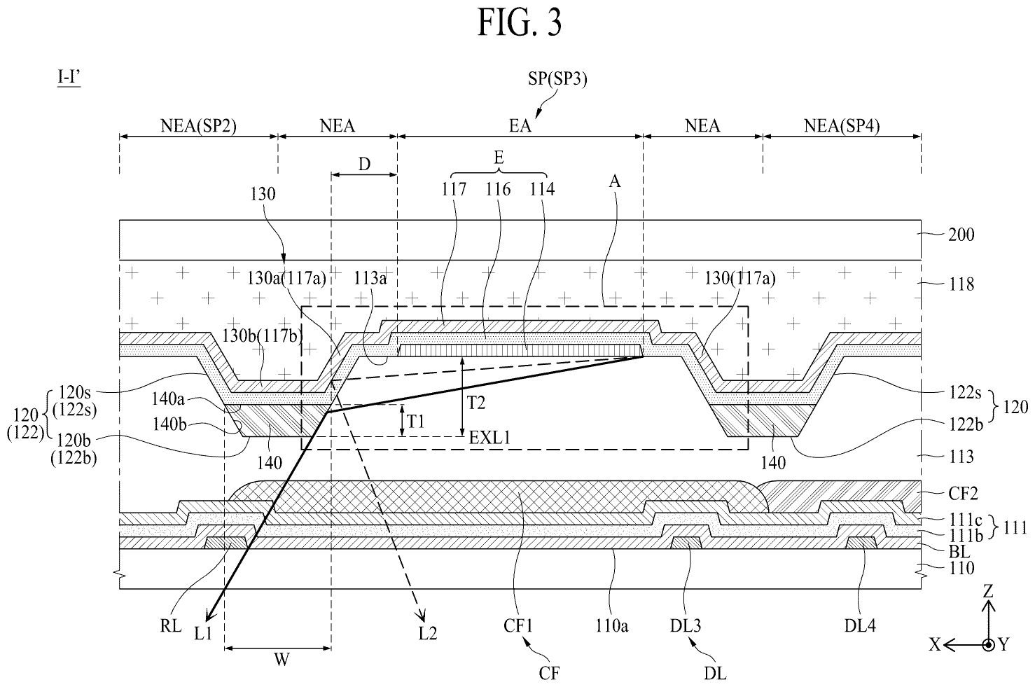

FIG. 1 is a schematic plan view of a display apparatus according to an example embodiment of the present disclosure, FIG. 2 is a schematic plan view of one example pixel illustrated in FIG. 1, and FIG. 3 is an example schematic cross-sectional view taken along a line I-I′ illustrated in FIG. 2.

As shown in FIGS. 1 to 3, a display apparatus 100 according to an example embodiment of the present disclosure may include a substrate 110 including a plurality of pixels including a plurality of sub-pixels SPs, a pattern portion 120 disposed on the substrate 110 and concavely formed in a non-light emission area NEA between the plurality of sub-pixels SPs, a reflective portion 130 disposed on the pattern portion 120, and a light rerouting layer 140 disposed below the reflective portion 130 in the pattern portion 120.

The pattern portion 120 may be formed on an overcoat layer 113 disposed on the substrate 110. The pattern portion 120 according to one example may be concave formed in the non-light emission area NEA by patterning and removing the overcoat layer 113 between a plurality of sub-pixels SPs. After the light rerouting layer 140 is formed on the concave formed the pattern portion 120, the organic light emitting layer 116 and a reflective electrode 117 may be deposited on the front side sequentially. Thus, as shown in FIG. 3, the organic light emitting layer 116 and the reflective electrode 117 may be concavely formed in the non-light emission area NEA along the profile of the pattern portion 120 and the light rerouting layer 140. Here, the reflective electrode 117 concavely formed in the non-light emission area NEA may be the reflective portion 130. The pattern portion 120, according to one example, may include a inclined surface 120s and a bottom surface 120b.

The bottom surface 120b of the pattern portion 120 may be a surface in parallel to an upper surface 110a of the substrate 110. In one example, the bottom surface 120b of the pattern portion 120 is a surface that is formed closest to the substrate 110 in the pattern portion 120 and may be disposed closer to the substrate 110 (or the upper surface 110a of the substrate) than the pixel electrodes 114 (or the lower surface of the pixel electrodes 114) in a light emission area EA.

The inclined surface 120s of the pattern portion 120 may be an inclined surface connected to the bottom surface 120b. In one example, the inclined surface 120s of the pattern portion 120 may form a predetermined angle with the bottom surface 120b. For example, the angle formed by the inclined surface 120s and the bottom surface 120b may be an obtuse angle. Accordingly, the pattern portion 120 may be provided to have the width of the pattern portion 120 decreases from the opposing substrate 200 (or reflective portion 130) toward the substrate 110 (or in the third direction (Z-axis direction)).

The third direction (Z-axis direction) according to an example may be a direction intersecting each of the first direction (X-axis direction) and the second direction (Y-axis direction) and may be a thickness direction of the display apparatus 100. The first direction (X-axis direction) may be a horizontal direction with reference to FIG. 1. The horizontal direction may be a direction in which the gate wiring is extended. The second direction (Y-axis direction) is a direction intersecting the first direction (X-axis direction) and may be a vertical direction relative to FIG. 1. The vertical direction may be a direction in which the data wiring is extended.

As the inclined surface 120s and the bottom surface 120b of the pattern portion 120 form an obtuse angle, the organic light emitting layer 116 and the reflective electrode 117 formed in the subsequent process may be formed to be concave along the profile of the pattern portion 120. Thus, the reflective portion 130 included in the reflective electrode 117 may be formed to be concave (or inclined) on the pattern portion 120 formed to be concave (or inclined) in the non-light emission area NEA (or a peripheral area). In other words, the organic light emitting layer 116 and the reflective electrode 117 formed in the subsequent process may be formed to comprise inclined portions having an inclination which corresponds to the inclination of the inclined surface 120s of the pattern portion 120.

The reflective portion 130, according to one example, is for reflecting light, which is emitted from the organic light emitting layer 116 and directed toward an adjacent sub-pixel SP, toward the emitting sub-pixel SP. The reflective portion 130 may include a first reflective portion 130a (117a) and a second reflective portion 130b (117b). The first reflective portion 130a (117a) may be disposed in an inclined angle on the pattern portion 120. The first reflective portion 130a (117a) may be disposed to be inclined along an inclined surface 120s of the pattern portion 120. The second reflective portion 130b (117b) may be connected to the first reflective portion 130a (117a) and may be disposed to be flat along the upper surface 140a of the light rerouting layer 140. As shown in FIG. 3, the first reflective portion 130a (117a) is disposed to be inclined on the pattern portion 120, and thus may be expressed in terms of a side surface reflective portion, an inclined reflective portion.

The light rerouting layer 140, according to one example, is for totally reflecting light that is emitted from the organic light emitting layer 116 and directed toward an adjacent sub-pixel SP through the overcoat layer 113. The light totally reflected by the light rerouting layer 140 may be directed toward the emitting sub-pixel SP or may be directed toward the non-light emission area NEA.

The light rerouting layer 140 may be provided to have a different refractive index than the overcoat layer 113. For example, the refractive index of the light rerouting layer 140 may be smaller than the refractive index of the overcoat layer 113. Accordingly, the display apparatus 100 according to an example embodiment of the present disclosure may totally reflect light directed to an adjacent sub-pixel SP by a difference in the refractive index of the light rerouting layer 140 and the overcoat layer 113. The light rerouting layer 140, according to one example, may include an organic material and/or an inorganic material.

As shown in FIG. 3, the reflective portion 130 (or the first reflective portion 130a) and the light rerouting layer 140 may be disposed on and below the inclined surface 120s of the pattern portion 120. Thus, the reflective portion 130 (or the first reflective portion 130a) may reflect light, which is emitted from the organic light emitting layer 116 and directed toward an adjacent sub-pixel SP (or the light emission area EA of an adjacent sub-pixel SP that is not emitting light), toward the emitting sub-pixel SP (or the non-light emission area NEA). And the light rerouting layer 140 disposed below the reflective portion 130 may totally reflect light emitted from the organic light emitting layer 116 and directed toward an adjacent sub-pixel SP (or the light emission area EA of an adjacent sub-pixel SP that is not emitting light). FIG. 3 illustrates that the totally reflected light being directed toward the non-light emission area NEA, but is not limited to, the light totally reflected by the light rerouting layer 140 may be directed toward the light emission area EA of the emitting sub-pixel SP.

Accordingly, the display apparatus 100 according to an example embodiment of the present disclosure is provided with a reflective portion 130 disposed in the pattern portion 120 formed to be concave between the plurality of sub-pixels SPs, and the light rerouting layer 140 disposed below the reflective portion 130 in the pattern portion 120, thus the light extraction efficiency in the light emission area EA and/or the non-light emission area NEA can be improved through the reflective portion 130 and the light rerouting layer 140.

As shown in FIG. 3, the light extraction efficiency may refer to the light extraction efficiency through a total reflection light L1 that is totally reflected by the light rerouting layer 140 and transmitted to the non-light emission area NEA, and the reflected light L2 that is reflected by the reflective portion 130 (or the first reflective portion 130a (117a)) and transmitted to the non-light emission area NEA or the light emission area EA of the emitting sub-pixel SP.

The pattern portion 120 may be provided to partially surround the light emission area EA, as shown in FIG. 2. By the pattern portion 120 being provided to partially surround the light emission area EA, at least a portion of the reflective portion 130, which is disposed to be inclined on the pattern portion 120, may also be provided to partially surround the light emission area EA. Further, the light rerouting layer 140 disposed on the pattern portion 120 may also be provided to partially surround the light emission area EA.

Accordingly, the display apparatus 100 according to an example embodiment of the present disclosure may have the same light emitting efficiency or the further improved light emitting efficiency at a lower power than a display apparatus without the reflective portion 130 and/or the light rerouting layer 140, since light extraction can be achieved even in the non-light emission area NEA that is the periphery of the light emission area EA through the reflective portion 130 and the light rerouting layer 140, and thus the overall power consumption may be reduced.

Furthermore, the display apparatus 100 according to an example embodiment of the present disclosure may have the same light emitting efficiency with lower power, thus the lifetime of the light emitting element layer E (or organic light emitting layer 116) may be improved.

On the other hand, in the display apparatus 100 according to an example embodiment of the present disclosure, the light rerouting layer 140 can be provided with an optimal thickness by a mathematical formula concerning the shape of the pattern portion 120, the refractive index of the light rerouting layer 140, the refractive index of the overcoat layer 113, the thickness of a portion of the overcoat layer 113, and a length of the pixel electrode 114, thereby maximizing the total reflectance efficiency of the light rerouting layer 140. A specific description of this will be described later.

Hereinafter, with reference to FIGS. 1 and 2, the display apparatus 100 according to an example embodiment of the present disclosure will be described in more detail.

As shown in FIGS. 1 and 2, the display apparatus 100 according to an example embodiment of the present disclosure may include a display panel having a gate driver GD, a source drive integrated circuit (hereinafter, referred to as “IC”) 150, a flexible film 160, a circuit board 170, and a timing controller 180.

The display panel may include a substrate 110 and an opposite substrate 200 (shown in FIG. 3).

The substrate 110 may include a thin film transistor, and may be a transistor array substrate, a lower substrate, a base substrate, or a first substrate. The substrate 110 may be a transparent glass substrate or a transparent plastic substrate. The substrate 110 may include a display area DA and a non-display area NDA.

The display area DA is an area where an image is displayed, and may be a pixel array area, an active area, a pixel array unit, a display unit, or a screen. For example, the display area DA may be disposed at a central portion of the display panel. The display area DA may include a plurality of pixels P.

The opposite substrate 200 may encapsulate (or seal) the display area DA disposed on the substrate 110. For example, the opposite substrate 200 may be bonded to the substrate 110 via an adhesive member (or clear glue). The opposite substrate 200 may be an upper substrate, a second substrate, or an encapsulation substrate.

The gate driver GD supplies gate signals to the gate lines in accordance with the gate control signal input from the timing controller 180. The gate driver GD may be formed on one side of the light emission area EA or in the non-light emission area NEA outside both sides of the light emission area EA in a gate driver in panel (GIP) method, as shown in FIG. 1.

The non-display area NDA is an area on which an image is not displayed, and may be a peripheral area, a signal supply area, an inactive area or a bezel area. The non-display area NDA may be configured to be in the vicinity of the display area DA. That is, the non-display area NDA may be disposed to surround the display area DA.

A pad area PA may be disposed in the non-display area NDA. The pad area PA may supply a power source and/or a signal for outputting an image to the pixel P provided in the display area DA. As shown in FIG. 1, the pad area PA may be provided above the display area DA.

The source drive IC 150 receives digital video data and a source control signal from the timing controller 180. The source drive IC 150 converts the digital video data into analog data voltages in accordance with the source control signal and supplies the analog data voltages to the data lines. When the source drive IC 150 is manufactured as a driving chip, the source drive IC 150 may be packaged in the flexible film 160 in a chip on film (COF) method or a chip on plastic (COP) method.

Pads, such as data pads, may be formed in the non-display area NDA of the display panel. Lines connecting the pads with the source drive IC 150 and lines connecting the pads with lines of the circuit board 170 may be formed in the flexible film 160. The flexible film 160 may be attached onto the pads by using an anisotropic conducting film, whereby the pads may be connected with the lines of the flexible film 160.

The circuit board 170 may be attached to the flexible films 160. A plurality of circuits implemented as driving chips may be packaged in the circuit board 170. For example, the timing controller 180 may be packaged in the circuit board 170. The circuit board 170 may be a printed circuit board or a flexible printed circuit board.

The timing controller 180 receives the digital video data and a timing signal from an external system board through a cable of the circuit board 170. The timing controller 180 generates a gate control signal for controlling an operation timing of the gate driver GD and a source control signal for controlling the source drive ICs 150 based on the timing signal. The timing controller 180 supplies the gate control signal to the gate driver GD and supplies the source control signal to the source drive ICs 150.

As shown in FIGS. 2 and 3, the substrate 110 according to an example may include the light emission area EA and the non-light emission area NEA.

The light emission area EA may mean an area from which light is emitted. A light emitting element layer E, which includes a pixel electrode 114, an organic light emitting layer 116 and a reflective electrode 117, may be disposed in the light emission area EA. When an electric field is formed between the pixel electrode 114 and the reflective electrode 117, the organic light emitting layer 116 in the light emission area EA may be emitted.

As shown in FIG. 3, a portion of the light emitted by the organic light emitting layer 116 may form the optical path toward an adjacent sub-pixel SP (or non-emitting sub-pixel) through the overcoat layer 113. The display apparatus 100 according to an example embodiment of the present disclosure may emit light, which is directed toward an adjacent sub-pixel, to the non-light emission area NEA or the light emission area EA, or reflect light, which is directed toward an adjacent sub-pixel, to the emitting sub-pixel, by that the reflective portion 130 and the light rerouting layer 140 are disposed between the sub-pixels SP. Accordingly, the display apparatus 100 according to an example embodiment of the present disclosure can improve the light efficiency of the emitting sub-pixel by extracting light directed toward the adjacent sub-pixel by the reflective portion 130 and the light rerouting layer 140. Furthermore, the display apparatus 100 according to an example embodiment of the present disclosure may prevent color mixing due to the reflective portion 130 and the light rerouting layer 140 disposed between the sub-pixels SPs.

As a result, the display apparatus 100 according to an example embodiment of the present disclosure may have an improved overall light efficiency while preventing color mixing with adjacent sub-pixels (or adjacent but non-emitting sub-pixels) through the reflective portion 130 and the light rerouting layer 140.

As shown in FIG. 2, the light emission area EA according to an example may include gate lines, data lines, pixel driving power lines, and a plurality of pixels P. Each of the plurality of pixels P may include a plurality of subpixels SP that may be defined by the gate lines and the data lines.

At least four subpixels, which are provided to emit light of different colors and disposed to be adjacent to one another, among the plurality of subpixels SP may constitute one pixel P (or unit pixel). One pixel P may include, but is not limited to, a red subpixel, a green subpixel, a blue subpixel and a white subpixel. One pixel P may include three subpixels SP provided to emit light of different colors and disposed to be adjacent to one another. For example, one pixel P may include a red subpixel, a green subpixel and a blue subpixel.

Each of the plurality of subpixels SP includes a thin film transistor and a light emitting element layer E connected to the thin film transistor. Each of the plurality of subpixels may include a light emitting layer (or an organic light emitting layer) interposed between the pixel electrode and the reflective electrode.

The light emitting layers disposed in each of the plurality of sub-pixels SP may emit white light in common. Since the light emitting layer of each of the plurality of sub-pixels SP emits white light in common, each of the red sub-pixel, the green sub-pixel, and the blue sub-pixel may include a color filter CF (or wavelength conversion member CF) that converts the white light to the respective colored light. In this case, the white sub-pixel may not comprise a color filter.

In the display apparatus 100 according to an example embodiment of the present disclosure, the area with the red color filter may be a red sub-pixel or a first sub-pixel, the area without the color filter may be a white sub-pixel or a second sub-pixel, the area with the blue color filter may be a blue sub-pixel or a third sub-pixel, and the area with the green color filter may be a green sub-pixel or a fourth sub-pixel.

Each of the subpixels SP supplies a predetermined current to the organic light emitting element in accordance with a data voltage of the data line when a gate signal is input from the gate line by using the thin film transistor. For this reason, the light emitting layer of each of the subpixels may emit light with a predetermined brightness in accordance with the predetermined current.

The plurality of subpixels SP according to one example may be disposed to be adjacent to each other in a first direction (X-axis direction).

The plurality of subpixels SP may include a first subpixel SP1, a second subpixel SP2, a third subpixel SP3 and a fourth subpixel SP4 arranged adjacent to each other in the first direction (X-axis direction). For example, the first subpixel SP1 may be a red subpixel, the second subpixel SP2 may be a whites subpixel, the third subpixel SP3 may be a blue subpixel and the fourth subpixel SP4 may be a green subpixel, but is not limited thereto. However, the arrangement order of the first subpixel SP1, the second subpixel SP2, the third subpixel SP3 and the fourth subpixel SP4 may be changed.

Each of the first to fourth subpixels SP1 to SP4 may include a light emission area EA and a circuit area CA. The light emission area EA may be disposed at one side (or an upper side) of a subpixel area, and the circuit area CA may be disposed at the other side (or a lower side) of the subpixel area. For example, the circuit area CA may be disposed at one side (or the lower side) of the light emission area EA based on the second direction (Y-axis direction). The light emission area EA of each of the first to fourth sub-pixels SP1 to SP4 may have the same size (or area) or different sizes (or areas) from each other.

The first to fourth subpixels SP1 to SP4 may be disposed to be adjacent to one another along the first direction (X-axis direction). For example, two data lines DL extended along the second direction (Y-axis direction) may be disposed in parallel with each other between the first subpixel SP1 and the second subpixel SP2 and between the third subpixel SP3 and the fourth subpixel SP4. A pixel power line EVDD (or branch wiring of the pixel power line) extended along the first direction (X-axis direction) may be disposed between the light emission area EA and the circuit area CA of each of the first to fourth subpixels SP1 to SP4. The gate line GL and a sensing line SL may be disposed below the circuit area CA. The pixel power line EVDD (shown in FIG. 2) extended along the second direction (Y-axis direction) may be disposed at one side of the first subpixel SP1 or the fourth subpixel SP4. A reference line RL extended along the second direction (Y-axis direction) may be disposed between the second subpixel SP2 and the third subpixel SP3. The reference line RL may be used as a sensing line for sensing a change of characteristics of a driving thin film transistor which is disposed in the circuit area and/or a change of characteristics of the light emitting element layer from the outside in a sensing driving mode of the pixel P. In one example, the data lines DL are for supplying data signals to each of the plurality of the sub-pixels SP to drive each of the plurality of the sub-pixels SP. For example, the data lines DL may include a first data line DL1 for driving a first sub-pixel SP1, a second data line DL2 for driving a second sub-pixel SP2, a third data line DL3 for driving a third sub-pixel SP3, and a fourth data line DL4 for driving a fourth sub-pixel SP4.

In the display apparatus 100 according to an example embodiment of the present disclosure, the data lines may be disposed not to overlap the light emission area EA. For example, the third data line DL3 may be arranged such that it does not overlap the light emission area EA. Thus, in the display apparatus 100 according to an example embodiment of the present disclosure, the third data line DL3 does not overlap (or is not interfered with) light emitted from the light emission area EA, thus a decrease in light extraction efficiency may be prevented. The first data line DL1, the second data line DL2, and the fourth data line DL4, like the third data line DL3, may be disposed in the non-light emission area NEA of the corresponding sub-pixel not to be overlapped the light emission area EA of the corresponding sub-pixel in the third direction (Z-axis direction). Thus, in the display apparatus 100 according to an example embodiment of the present disclosure, the data lines DL1, DL2, DL3, DL4 may have a structural feature that do not overlap the light emission area EA but overlap the non-light emission area NEA.

On the other hand, since the pixel power line EVDD and the reference line RL each have a wide width compared to the data line, the pixel power line EVDD and the reference line RL may be disposed in a position that does not obscure the light totally reflected from the interface of the light rerouting layer 140 and the overcoat layer 113, as shown in FIG. 3.

In the display apparatus 100 according to an example embodiment of the present disclosure, each of the plurality of the sub-pixels SP may include the light emission area EA disposed adjacent to the non-light emission area NEA. As shown in FIG. 3, the light rerouting layer 140 may be spaced apart from the light emission area EA. For example, the light rerouting layer 140 may be disposed spaced apart from the light emission area EA by a predetermined distance D (or a first distance D). This is because if the light rerouting layer is not spaced apart from the light emission area, but is disposed adjacent to the light emission area or overlaps the light emission area, the light directed toward the light rerouting layer is incident at an angle smaller than a threshold angle at which the light can be totally reflected, and thus the light rerouting layer is not able to totally reflect the light.

Accordingly, in the display apparatus 100 according to an example embodiment of the present disclosure, the light rerouting layer 140 is spaced apart from the light emission area EA, thus light directed toward the adjacent second sub-pixel SP2 among the light emitted from the light emission area EA can be totally reflected, thereby improving the light extraction efficiency. The light rerouting layer 140 may be provided to have smaller refractive index than the refractive index of the overcoat layer 113, thereby enabling light to be totally reflected. For example, as shown in FIG. 3, the light rerouting layer 140 may totally reflect light directed to the second sub-pixel SP2 among the light emitted by the organic light emitting layer 116, which is disposed at an edge of the pixel electrode 114 (or the other side of the pixel electrode 114 opposite to one side of the pixel electrode 114), to the non-light emission area NEA.

Meanwhile, as shown in FIG. 3, the light emission area EA is the area defined by the pixel electrodes 114 disposed on the overcoat layer 113, thus the light rerouting layer 140 may be spaced apart from the pixel electrodes 114. The light rerouting layer 140, according to one example, may include an upper surface 140a and a side surface 140b. The upper surface 140a of the light rerouting layer 140 may be a surface that contacts the organic light emitting layer 116 in the pattern portion 120. A side surface 140b of the light rerouting layer 140 may be a surface contacts the inclined surface 120s of the pattern portion 120. Because the light rerouting layer 140 is formed through a process in which the pattern portion 120 is formed and then the light rerouting layer 140 is filled into the pattern portion 120, the light rerouting layer 140 may be in contact with the entire bottom surface 120b of the pattern portion 120 and partially in contact with the inclined surface 120s of the pattern portion 120. However, it is not limited to, the light rerouting layer 140 may be in contact with the entire bottom surface 120b of the pattern portion 120 and may be in contact with the entire inclined surface 120s of the pattern portion 120.

As shown in FIG. 3, the width W of the light rerouting layer 140 may decrease as one moves from the reflective portion 130 toward the substrate 110. For example, the width W of the light rerouting layer 140 may decrease as one moves from the reflective portion 130 toward the third direction (Z-axis direction), which is toward the substrate 110. Accordingly, the side surface 140b of the light rerouting layer 140 may be disposed inclined in the pattern portion 120. For example, the side surface 140b of the light rerouting layer 140 may be disposed inclined to have an acute angle with respect to the upper surface 110a of the substrate 110. Thus, light directed toward the adjacent second sub-pixel SP2 among light emitted from the third sub-pixel SP3 may be totally reflected in an interface (or boundary surface) between the side surface 140b of the light rerouting layer 140 and the overcoat layer 113 and may be transmitted into the non-light emission area NEA or the light emission area EA.

In the display apparatus 100 according to an example embodiment of the present description, the thickness T1 of the light rerouting layer 140 may be thinner than or equal to a vertical thickness T2 between an extension line EXL1 (or a first extension line EXL1) extended in the first direction (X-axis direction) from the bottom surface 120b of the pattern portion 120, and the upper surface 113a of the overcoat layer 113. Hereinafter, for ease of description, the vertical thickness T2 between the first extension line EXL1 and the upper surface 113a of the overcoat layer 113 is defined as the thickness T2 of the overcoat layer 113.

For example, as shown in FIG. 3, if the thickness T1 of the light rerouting layer 140 is thinner than the thickness T2 of the overcoat layer 113, the reflective electrode 117 may be concave into the pattern portion 120 by a step difference between the thickness T2 of the overcoat layer 113 and the thickness T1 of the light rerouting layer 140, which may cause the reflective portion 130 (or the first reflective portion 130a) to be disposed on the inclined surface 120s of the pattern portion 120. Thus, the reflective portion 130 (or the first reflective portion 130a) and the light rerouting layer 140 are disposed on and below the pattern portion 120, light directed toward the adjacent second sub-pixel SP2 among light emitted by the organic light emitting layer 116 (or the organic light emitting layer 116 of the third sub-pixel SP3) may be reflected by the reflective portion 130 (or the first reflective portion 130a) and transmitted to the emitting sub-pixel (or the third sub-pixel SP3). Furthermore, since the reflective portion 130 (or the first reflective portion 130a) and the light rerouting layer 140 are disposed on and below the pattern portion 120, light directed toward the adjacent second sub-pixel SP2 among light emitted from the organic light emitting layer 116 (or the organic light emitting layer 116 of the third sub-pixel SP3) may be totally reflected in the interface between the light rerouting layer 140 and the overcoat layer 113 to transmit toward the non-light emission area NEA (e.g., the non-light emission area NEA between the second sub-pixel SP2 and the third sub-pixel SP3) or toward the light emission area EA of the third sub-pixel SP3.

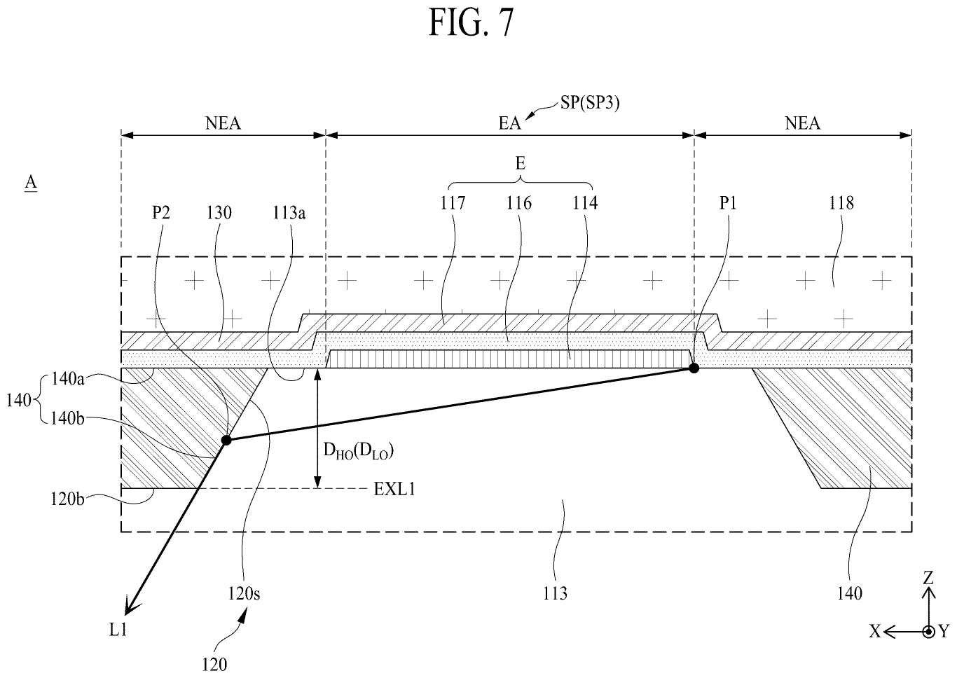

On the other hand, if the thickness T1 of the light rerouting layer 140 is equal to the thickness T2 of the overcoat layer 113, the light rerouting layer 140 may be provided to fill the pattern portion 120 entirely. In this case, the thickness T1 of the light rerouting layer 140 does not differ from the thickness T2 of the overcoat layer 113, thus a step difference may not occur between the light rerouting layer 140 and the overcoat layer 113. Therefore, the reflective electrode 117 may be provided flatly on the pattern portion 120. In this case, the reflective electrode 117 may not be formed to be concave on the pattern portion 120, and thus, a short circuit of the reflective electrode 117 may be prevented. This will be described further with reference to FIG. 7.

In the display apparatus 100 according to an example embodiment of the present disclosure, the light rerouting layer 140 may be provided to surround the remainder of the light emission area EA except for at least a portion of one side of the light emission area EA where the circuit area CA is provided. For example, as shown in FIG. 2, the light rerouting layer 140 may not be disposed on at least a portion of one side of the light emission area EA adjacent to the circuit area CA but may be disposed only on sides of the light emission area EA where the pattern portion 120 is formed except for the at least portion of the one side. This is because the pixel electrode 114 disposed in the light emission area EA needs to be connected to the circuit area CA, thus the pattern portion 120 is not able to be formed between the light emission area EA and the circuit area CA. Accordingly, the light rerouting layer 140 is able to be disposed only in the area where the pattern portion 120 is formed. Therefore, as shown in FIG. 2, the display apparatus 100 according to an example embodiment of the present disclosure may have a structural feature in which the light rerouting layer 140 is disposed to surround the remainder of the light emission area EA except for the at least portion of one side of the light emission area EA where the circuit area CA is provided.

As shown in FIG. 2, the pattern portion 120 may include a first pattern line 121 disposed in the first direction (X-axis direction) between the circuit area CA and the light emission area EA and a second pattern line 122 disposed in the second direction (Y-axis direction) crossing the first direction (X-axis direction). As shown in FIG. 2, the first pattern line 121 may mean the pattern portion 120 disposed in a horizontal direction, and the second pattern line 122 may mean the pattern portion 120 disposed in a vertical direction.

The first pattern line 121 may include a bottom surface 121b and an inclined surface 121s. The second pattern line 122 may include a bottom surface 122b and an inclined surface 122s. Since each of the bottom surface 121b and the inclined surface 121s of the first pattern line 121 and each of the bottom surface 122b and the inclined surface 122s of the second pattern line 122 are the same as each of the bottom surface 120b and the inclined surface 120s of the pattern portion 120, their description will be omitted. The first pattern line 121 and the second pattern line 122 may be connected to with each other in the non-light emission area NEA (or the peripheral area) to surround the light emission area EA.

The first pattern line 121 may be disposed between the subpixels SP for emitting light of the same color. For example, the first pattern line 121 may be disposed between the first subpixels SP1 disposed in the second direction (Y-axis direction). Therefore, the first pattern line 121 may be disposed in the first direction (X-axis direction). In contrast, the second pattern line 122 may be disposed between the subpixels SP for emitting light of different colors. For example, the second pattern line 122 may be disposed between the third subpixel SP3 that is a blue subpixel, and the fourth subpixel SP4 that is a green subpixel. Therefore, the second pattern line 122 may be disposed in the second direction (Y-axis direction).

Since the second pattern line 122 is disposed between the subpixels SP for emitting light of different colors, the reflective portion 130 on the second pattern line 122 may prevent light of different colors from being emitted to other adjacent subpixels SP. Therefore, the display apparatus 100 according to the present disclosure may prevent color mixture (or color distortion) between the subpixels SP for emitting light of different colors, thereby improving color purity.

In the display apparatus 100 according to an example embodiment of the present disclosure, the light rerouting layer 140 may be disposed on the first pattern line 121 and the second pattern line 122, which are surrounding the light emission area EA except between the light emission area EA and the circuit area CA.

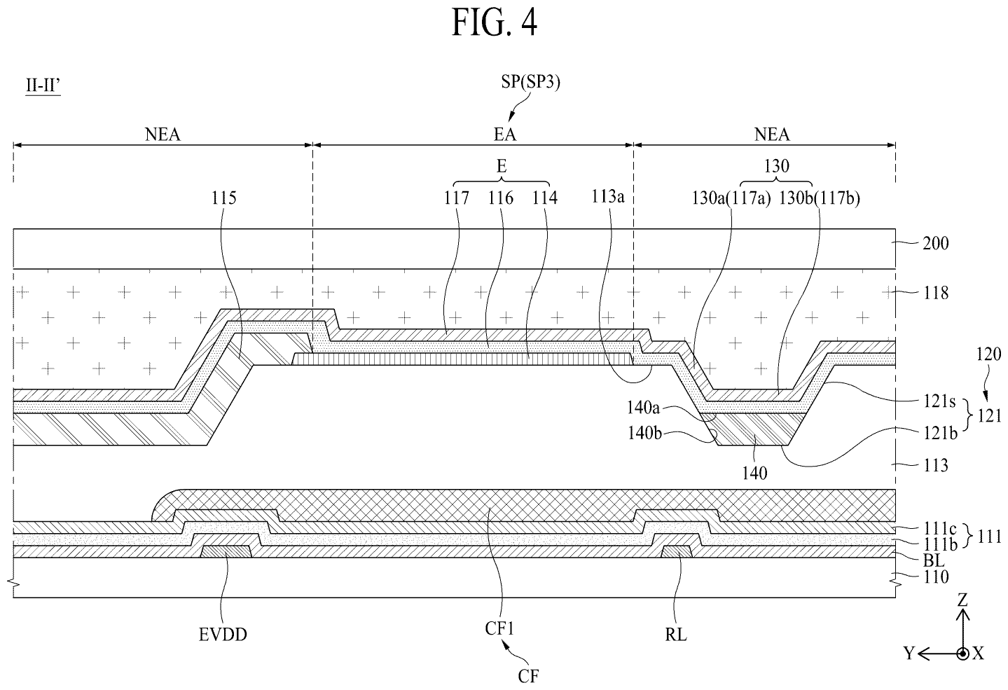

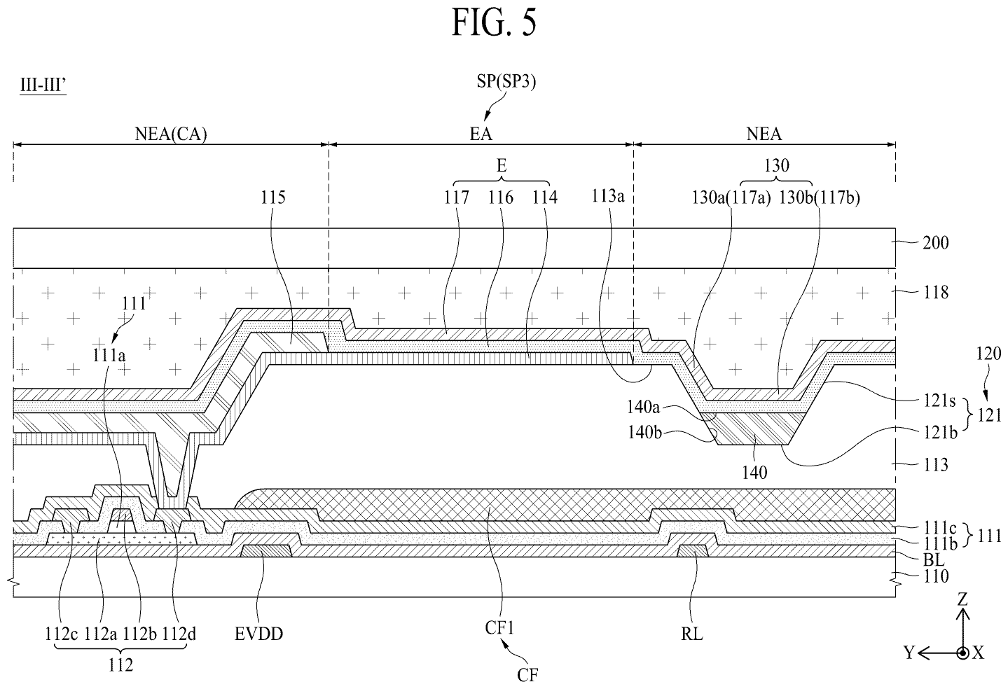

FIG. 4 is a schematic cross-sectional view taken along a line II-II′ illustrated in FIG. 2, and FIG. 5 is a schematic cross-sectional view taken along a line III-III′ illustrated in FIG. 2.

As shown in FIG. 4, the light rerouting layer 140 is disposed to surround the remainder of the light emission area EA except for at least a portion of one side of the light emission area EA where the circuit area CA is disposed, thus the light rerouting layer 140 may not be disposed in the non-light emission area NEA adjacent to the circuit area CA. And, since the bank 115 is disposed to cover the circuit area CA (or thin film transistor 112, shown in FIG. 5), the light rerouting layer 140 may not be disposed in the non-light emission area NEA in which the circuit area CA is disposed. This is because if the light rerouting layer 140 is disposed in the non-light emission area NEA in which the circuit area CA is disposed, light totally reflected in the interface between the light rerouting layer 140 and the overcoat layer 113 may be incident on the circuit area CA, causing the thin film transistor 112 to deteriorate and become damaged, or causing light to be reflected on the metal wiring in the circuit area CA, making the circuit area visible to a user. Therefore, the display apparatus 100 according to an example embodiment of the present disclosure is provided that the light rerouting layer 140 is not disposed in the non-light emission area NEA in which the circuit area CA is disposed, thus the deterioration of the service life of the thin film transistor 112 may be prevented and the circuit area may be prevented from being visible to a user.

On the other hand, as shown in FIGS. 4 and 5, each of the pixel power line EVDD and the reference line RL may be disposed not to overlap the light emission area EA in the third direction (Z-axis direction). Thus, the display apparatus 100 according to an example embodiment of the present disclosure may enable light emitted from the light emission area EA to be transmitted to the outside of the substrate 110 without interference from the pixel power lines EVDD and the reference line RL, and thus a decrease of light emission efficiency may be prevented.

Hereinafter, as shown in FIG. 5, a structure of each of the plurality of subpixels SP will be described in detail.

As shown in FIG. 5, the display apparatus 100 according to an example embodiment of the present disclosure may further include a buffer layer BL, a circuit element layer 111, a thin film transistor 112, an overcoat layer 113, a pixel electrode 114, a bank 115, an organic light emitting layer 116, a reflective electrode 117, an encapsulation layer 118 and a color filter CF.

In more detail, each of the subpixels SP according to an example embodiment may include a circuit element layer 111 provided on an upper surface of a buffer layer BL, including a gate insulating layer 111a, an interlayer insulating layer 111b and a passivation layer 111c, an overcoat layer 113 provided on the circuit element layer 111, a pixel electrode 114 provided on the overcoat layer 113, a bank 115 covering an edge of the pixel electrode 114, an organic light emitting layer 116 on the pixel electrode 114 and the bank 115, a reflective electrode 117 on the organic light emitting layer 116, and an encapsulation layer 118 on the reflective electrode 117.

The thin film transistor 112 for driving the subpixel SP may be disposed on the circuit element layer 111. The circuit element layer 111 may be expressed as the term of an inorganic film layer. The buffer layer BL may be included in the circuit element layer 111 together with the gate insulating layer 111a, the interlayer insulating layer 111b and the passivation layer 111c. The pixel electrode 114, the organic light emitting layer 116 and the reflective electrode 117 may be included in the light emitting element layer E.

The buffer layer BL may be formed between the substrate 110 and the gate insulating layer 111a to protect the thin film transistor 112. The buffer layer BL may be disposed on the entire surface (or front surface) of the substrate 110. The pixel power line EVDD for pixel driving may be disposed between the buffer layer BL and the substrate 110. The pixel power line EVDD may be disposed below the bank 115 while being spaced apart from the thin film transistor 112. The reference line RL may also be disposed between the buffer layer BL and the substrate 110. The reference line RL may be disposed in the non-light emission area NEA that does not overlap with the light emission area EA. The buffer layer BL may serve to block diffusion of a material contained in the substrate 110 into a transistor layer during a high temperature process of a manufacturing process of the thin film transistor. Optionally, the buffer layer BL may be omitted in some cases.

The thin film transistor 112 (or a drive transistor) according to an example may include an active layer 112a, a gate electrode 112b, a source electrode 112c, and a drain electrode 112d.

The active layer 112a may include a channel area, a drain area and a source area, which are formed in a thin film transistor area of a circuit area of the subpixel SP. The drain area and the source area may be spaced apart from each other with the channel area interposed therebetween.

The active layer 112a may be formed of a semiconductor material based on any one of amorphous silicon, polycrystalline silicon, oxide and organic material.

The gate insulating layer 111a may be formed on the channel area of the active layer 112a. As an example, the gate insulating layer 111a may be formed in an island shape only on the channel area of the active layer 112a, or may be formed on an entire front surface of the substrate 110 or the buffer layer BL, which includes the active layer 112a.

The gate electrode 112b may be formed on the gate insulating layer 111a to overlap the channel area of the active layer 112a.

The interlayer insulating layer 111b may be formed on the gate electrode 112b and the drain area and the source area of the active layer 112a. As in FIG. 5, the interlayer insulating layer 111b may be formed in the circuit area and an entire light emission area, in which light is emitted in the subpixel SP. However, embodiments of the present disclosure are not limited thereto, the interlayer insulating layer 111b may be patterned between the drain electrode 112d and the gate electrode 112b and drain region of the active layer 112a and may be arranged in an island shape, and moreover, may be patterned between the source electrode 112c and the gate electrode 112b and source region of the active layer 112a and may be arranged in an island shape.

The source electrode 112c may be electrically connected to the source area of the active layer 112a through a source contact hole provided in the interlayer insulating layer 111b overlapped with the source area of the active layer 112a. The drain electrode 112d may be electrically connected to the drain area of the active layer 112a through a drain contact hole provided in the interlayer insulating layer 111b overlapped with the drain area of the active layer 112a.

The drain electrode 112d and the source electrode 112c may be made of the same metal material. For example, each of the drain electrode 112d and the source electrode 112c may be made of a single metal layer, a single layer of an alloy or a multi-layer of two or more layers, which is the same as or different from that of the gate electrode.

In addition, the circuit area may further include first and second switching thin film transistors disposed together with the thin film transistor 112, and a capacitor. Since each of the first and second switching thin film transistors is provided on the circuit area of the subpixel SP to have the same structure as that of the thin film transistor 112, its description will be omitted. The capacitor (not shown) may be provided in an overlap area between the gate electrode 112b and the source electrode 112c of the thin film transistor 112, which overlap each other with the interlayer insulating layer 111b interposed therebetween.

Additionally, in order to prevent a threshold voltage of the thin film transistor provided in a pixel area from being shifted by light, the display panel or the substrate 110 may further include a light shielding layer (not shown) provided below the active layer 112a of at least one of the thin film transistor 112, the first switching thin film transistor or the second switching thin film transistor. The light shielding layer may be disposed between the substrate 110 and the active layer 112a to shield light incident on the active layer 112a through the substrate 110, thereby minimizing a change in the threshold voltage of the transistor due to external light. Also, since the light shielding layer is provided between the substrate 110 and the active layer 112a, the thin film transistor may be prevented from being seen by a user.

The passivation layer 111c may be provided on the substrate 110 to cover the pixel area. The passivation layer 111c covers a drain electrode 112d, a source electrode 112c and a gate electrode 112b of the thin film transistor 112, and the buffer layer BL.

On the other hand, the display apparatus 100 according to an example embodiment of the present disclosure may be provided that the bank 115 is disposed only on one side of the light emission area EA in which the circuit area CA is disposed. Accordingly, as shown in FIG. 5, the pixel power line EVDD may be disposed to overlap the bank 115 in the third direction (Z-axis direction), and the reference line RL may not overlap the bank 115 in the third direction (Z-axis direction). The passivation layer 111c may be formed over the circuit area and the light emission area. The passivation layer 111c may be omitted. The color filter CF may be disposed on the passivation layer 111c.

The overcoat layer 113 may be provided on the substrate 110 to cover the passivation layer 111c and the color filter CF. When the passivation layer 111c is omitted, the overcoat layer 113 may be provided on the substrate 110 to cover the circuit area. The overcoat layer 113 may be formed in the circuit area CA in which the thin film transistor 112 is disposed and the light emission area EA. In addition, the overcoat layer 113 may be formed in the other non-display area NDA except a pad area PA of the non-display area NDA and the entire display area DA. For example, the overcoat layer 113 may include an extension portion (or an enlarged portion) extended or enlarged from the display area DA to the other non-display area NDA except the pad area PA. Therefore, the overcoat layer 113 may have a size relatively wider than that of the display area DA.

The overcoat layer 113 according to one example may be formed to have a relatively thick thickness, thereby providing a flat surface on the display area DA and the non-display area NDA. For example, the overcoat layer 113 may be made of an organic material such as photo acryl, benzocyclobutene, polyimide and fluorine resin.

By being provided with an upper surface 113a of the overcoat layer 113 to be flat, the pixel electrodes 114 on the overcoat layer 113 may also be provided to be flat, and the organic light emitting layer 116 and reflective electrodes 117 formed thereon may also be provided to be flat. Since the pixel electrode 114, the organic light emitting layer 116, the reflective electrode 117, that is, the light emitting element layer E is provided to be flat in the light emission area EA, a thickness of each of the pixel electrode 114, the organic light emitting layer 116 and the reflective electrode 117 in the light emission area EA may be uniformly formed. Therefore, the organic light emitting layer 116 may uniformly emit light without deviation in the light emission area EA.

On the other hand, a portion of the overcoat layer 113 may be patterned and removed, thereby forming the pattern portion 120. The pattern portion 120, according to one example, may be formed on the overcoat layer 113 by a photo process utilizing a mask having an opening, and by a patterning (or etching) or ashing process after the photo process. As described above, the pattern portion 120 may include a first pattern line 121 and a second pattern line 122, and the first pattern line 121 and the second pattern line 122 may be disposed to surround the remainder of the light emission area EA except for one side of the light emission area EA to which the circuit area CA is adjacent. After the pattern portion 120 is formed, the light rerouting layer 140 may be filled into the pattern portion 120, and then the organic light emitting layer 116 and the reflective electrode 117 may be formed on the front side.

Referring again to FIG. 5, the color filter CF disposed in the light emission area EA may be provided between the substrate 110 (or passivation layer 111c) and the overcoat layer 113. Accordingly, color filter CF may be disposed between the reference line RL and the reflective portion 130 or between the reference line RL and the pattern portion 120. The color filter CF may include a red color filter (or a third color filter) (not shown) that converts white light emitted by the organic light emitting layer 116 into red light, a green color filter (or a first color filter) (CF1) that converts white light into green light, and a blue color filter (or a second color filter) (CF2, shown in FIG. 3) that converts white light into blue light. The second sub-pixel SP2, which is a white sub-pixel, may not include a color filter because the organic light emitting layer 116 emits white light.

As shown in FIG. 3, the display apparatus 100 according to an example embodiment of the present disclosure may be provided such that color filters (e.g., the first color filter (CF1) and the second color filter (CF2)) having different colors partially overlap each other at a boundary portion of the plurality of subpixels SP. In this case, the display apparatus 100 according to an example embodiment of the present disclosure may prevent the light emitted from each subpixel SP from being emitted to the adjacent subpixel SP due to the color filters overlapped with each other at the boundary portion of the subpixels SP, thereby preventing color mixture between the subpixels SP from occurring.

Referring again back to FIG. 5, the pixel electrode 114 of the subpixel SP may be formed on the overcoat layer 113. The pixel electrode 114 may be connected to a drain electrode or a source electrode of the thin film transistor 112 through a contact hole passing through the overcoat layer 113 and the passivation layer 111c. The one edge portion of the pixel electrode 114 may be covered by the bank 115. The pixel electrode 114 may be made of at least one of a transparent metal material or a semi-transmissive metal material.

Because the display apparatus 100 according to an embodiment of the present disclosure is configured as the bottom emission type, the pixel electrode 114 may be formed of a transparent conductive material (or TCO), such as indium tin oxide (ITO) or indium zinc oxide (IZO) capable of transmitting light, or a semi-transmissive conductive material such as magnesium (Mg), silver (Ag), or an alloy of Mg and Ag.

Meanwhile, the material constituting the pixel electrode 114 may include MoTi. The pixel electrode 114 may be a first electrode or an anode electrode.

The bank 115 may be an area, which does not emit light, and disposed on one side of the light emission area EA of each of the plurality of sub-pixels SP. For example, the bank 115 may be disposed in the non-light emission area NEA where the circuit area CA is disposed. As shown in FIG. 5, the bank 115 may be formed to cover a portion where one edge of the pixel electrode 114 in each of the sub-pixels SP is connected to the thin film transistor 112. That is, the bank 115 may partially cover the pixel electrode 114. Accordingly, the bank 115 may prevent the pixel electrode 114 and reflective electrode 117 from contacting in the circuit area CA. The exposed portion of the pixel electrode 114 that is not covered by the bank 115 may be included in the light emitting portion (or light emission area EA).

As described above, the bank 115 is disposed in the non-light emission area NEA in which the circuit area CA is disposed, thus the left non-light emission area NEA and the right non-light emission area NEA may be asymmetrically provided relative to the light emission area EA of FIG. 5. For example, relative to the light emission area EA of FIG. 5, the left non-light emission area NEA may be provided as a structure including the thin film transistor 112 and without the light rerouting layer 140, and the right non-light emission area NEA may be provided as a structure in which the pattern portion 120 is partially filled with the light rerouting layer 140.

After the bank 115 is formed, an organic light emitting layer 116 may be formed to cover the pixel electrodes 114 and the bank 115. Thus, the bank 115 may be provided between the pixel electrodes 114 and the organic light emitting layer 116. The bank 115 may be expressed in terms of a pixel-defining membrane. The bank 115 according to one example may comprise organic material and/or inorganic material. The banks 115 according to one example may be concave or inclined along the profile of the pattern portion 120.

Referring again back to FIG. 5, the organic light emitting layer 116 may be formed on the pixel electrodes 114 and the bank 115. According to one example, the organic light emitting layer 116 may be disposed in the light emission area EA and the non-light emission area NEA. The organic light emitting layer 116 may be provided between the pixel electrode 114 and the reflective electrode 117. Thus, when a voltage is applied to each of the pixel electrode 114 and the reflective electrode 117, an electric field is formed between the pixel electrode 114 and the reflective electrode 117. Therefore, the organic light emitting layer 116 may emit light. The organic light emitting layer 116 may be formed of a plurality of subpixels SP and a common layer provided on the bank 115.

The organic light emitting layer 116 according to an embodiment may be provided to emit white light. The organic light emitting layer 116 may include a plurality of stacks which emit lights of different colors. For example, the organic light emitting layer 116 may include a first stack, a second stack, and a charge generating layer (CGL) provided between the first stack and the second stack. The light emitting layer may be provided to emit the white light, and thus, each of the plurality of subpixels SP may include a color filter CF suitable for a corresponding color.

The first stack may be provided on the pixel electrode 114 and may be implemented a structure where a hole injection layer (HIL), a hole transport layer (HTL), an emission layer (EML (B)), and an electron transport layer (ETL) are sequentially stacked.

The charge generating layer may supply an electric charge to the first stack and the second stack. The charge generating layer may include an N-type charge generating layer for supplying an electron to the first stack and a P-type charge generating layer for supplying a hole to the second stack. The N-type charge generating layer may include a metal material as a dopant.

The second stack may be provided on the first stack and may be implemented in a structure where a hole transport layer (HTL), a yellow-green (YG) emission layer (EML (YG)), and an electron injection layer (EIL) are sequentially stacked.

In the display apparatus 100 according to an embodiment of the present disclosure, because the organic light emitting layer 116 is provided as a common layer, the first stack, the charge generating layer, and the second stack may be arranged all over the plurality of subpixels SP. The organic light emitting layer 116, according to another example, may be provided in a three-stacked structure or a four-stacked structure, depending on the number of stacks stacked.

The reflective electrode 117 may be formed on the organic light emitting layer 116. The reflective electrodes 117 may be disposed in the light emission area EA and the non-light emission area NEA. The reflective electrode 117 according to one example may include a metal material. The reflective electrode 117 may reflect the light emitted from the organic light emitting layer 116 in the plurality of subpixels SP toward the lower surface of the substrate 110. Therefore, the display apparatus 100 according to an example embodiment of the present disclosure may be implemented as a bottom emission type display apparatus.

The display apparatus 100 according to an example embodiment of the present disclosure is a bottom emission type and it may be necessary to reflect light emitted from the organic light emitting layer 116 toward the substrate 110, and thus the reflective electrode 117 may be made of a metal material having high reflectance. The reflective electrode 117 according to one example may be formed of a metal material having high reflectance such as a stacked structure (Ti/Al/Ti) of aluminum and titanium, a stacked structure (ITO/Al/ITO) of aluminum and ITO, an Ag alloy and a stacked structure (ITO/Ag alloy/ITO) of Ag alloy and ITO. The Ag alloy may be an alloy such as silver (Ag), palladium (Pd) and copper (Cu). The reflective electrode 117 may be expressed as terms such as a second electrode, a cathode electrode and a counter electrode.

On the other hand, in the display apparatus 100 according to an example embodiment of the present disclosure, the reflective portion 130 may be a part of the reflective electrode 117. Thus, the reflective portion 130 may reflect light, which is directed toward the adjacent sub-pixel SP, toward the light emission area EA of the emitting sub-pixel SP. Since the reflective portion 130 is part of the reflective electrode 117, the first reflective portion 130a may be denoted by the drawing symbol of 117a, and the second reflective portion 130b may be denoted by the drawing symbol of 117b, as shown in FIG. 3. The reflective portion 130 may refer to the reflective electrode 117 overlapping the pattern portion 120. In particular, the reflective portion 130 may refer to a reflective electrode 117 overlapping the pattern portion 120 and inclined, i.e., the first reflective portion 130a (or the first reflective electrode 117a). Accordingly, the reflective portion 130 (or the first reflective portion 130a) may reflect light, which is directed toward the adjacent sub-pixel SP, and/or light, which is extinct through total reflection between an interface, to the light emission area EA and/or the non-light emission area NEA of the emitting sub-pixel SP, as shown in FIG. 3.

The encapsulation layer 118 is formed on the reflective electrode 117. The encapsulation layer 118 serves to prevent oxygen or moisture from being permeated into the organic light emitting layer 116 and the reflective electrode 117. To this end, the encapsulation layer 118 may include at least one inorganic film and at least one organic film.

Meanwhile, as shown in FIG. 3, the encapsulation layer 118 may be disposed not only in the light emission area EA but also in the non-light emission area NEA. The encapsulation layer 118 may be disposed between the reflective electrode 117 and an opposing substrate 200.

In the display apparatus 100 according to an example embodiment of the present disclosure, the organic light emitting layer 116 and the reflective electrode 117 may be formed sequentially after the pattern portion 120 is firstly formed and the light rerouting layer 140 is secondly filled in the pattern portion 120. Thus, as shown in FIG. 3, the organic light emitting layer 116 may be disposed in the pattern portion 120 between the first reflective portion 130a and the inclined surface 120s of the pattern portion 120, and between the second reflective portion 130b and the light rerouting layer 140 (or the upper surface 140a of the light rerouting layer 140).

As the display apparatus 100 according to an example embodiment of the present disclosure is provided that the reflective portion 130 is disposed on the upper side of the light rerouting layer 140, the depth at which the reflective portion 130, which is part of the reflective electrode 117, is disposed on the pattern portion 120 may be lowered compared to the case of a display apparatus without the light rerouting layer. That is, a step difference between the reflective electrode 117 disposed on the upper surface 113a of the overcoat layer 113 and the reflective electrode 117 (or the second reflective portion 130b) disposed on the pattern portion 120 may be reduced. Accordingly, the display apparatus 100 according to an example embodiment of the present disclosure may prevent short-circuiting of the reflective electrodes compared to a display apparatus without the light rerouting layer 140 in the pattern portion 120.

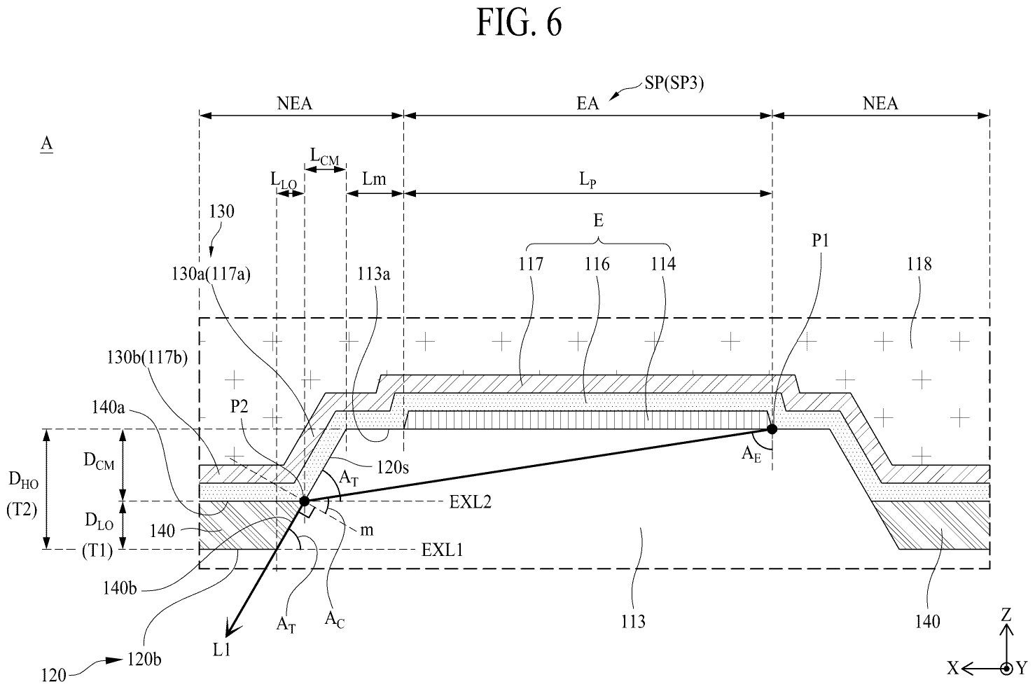

Hereinafter, with reference to FIG. 6, the thickness of the light rerouting layer 140 comprised in the display apparatus 100 according to an example embodiment of the present disclosure will be described in detail by associating mathematical expressions.

FIG. 6 is a schematic enlarged cross-sectional view of portion A illustrated in FIG. 3.

As shown in FIG. 6, the light rerouting layer 140 may be provided with the optimal thickness based on a mathematical formula relating the shape of the pattern portion 120, the refractive index of the light rerouting layer 140 and the refractive index of the overcoat layer 113, the thickness of a portion of the overcoat layer 113, and the length of the pixel electrode 114.

The thickness (D_{LO}) of the light rerouting layer 140 (or the thickness (T1) of the light rerouting layer 140), according to one example, is provided to satisfy a mathematical expression (or Equation 1) as shown below:

$${D}_{LO} = {D}_{HO} - {D}_{CM}$$

D_{HO} denotes a vertical length between the extension line (EXL1) (or the first extension line (EXL1)) extended from the bottom surface 120b of the pattern portion 120 and the upper surface 113a of the overcoat layer 113, and D_{CM} denotes a vertical length between the upper surface 140a of the light rerouting layer 140 and the upper surface 113a of the overcoat layer 113. The thickness D_{LO} of the light rerouting layer 140 may refer to a vertical length of the light rerouting layer 140, and the vertical length may be parallel to the third direction (Z-axis direction). As described above, in the present disclosure, D_{HO} may denote a thickness of the overcoat layer 113.

Meanwhile, in the above Equation 1, the vertical length D_{CM} between the upper surface 140a of the light rerouting layer 140 and the upper surface 113a of the overcoat layer 113 is provided to satisfy the following mathematical expression (or Equation 2):

$${D}_{CM} = ( {L}_{CM} + {L}_{m} + {L}_{P} ) * tan ( {A}_{C} + {A}_{T} - 90 ° )$$

L_{CM} denotes a horizontal length (or a horizontal length in the first direction (X-axis direction)) from the point P2 (or the second point P2) where the upper surface 140a of the light rerouting layer 140 and the inclined surface 120s of the pattern portion 120 meet to one end of the upper surface 113a (for example, one end of the upper surface 113a adjacent to the second point P2) of the overcoat layer 113, and Lₘ denotes a shortest length between the one end of the upper surface 113a of the overcoat layer 113 and one end of the pixel electrode 114 (for example, one end of the pixel electrode 114 adjacent to the second point P2), L_{P} denotes the length of the pixel electrode 114, and A_{C} denotes an angle (in some examples, a critical angle) between a normal m to the inclined surface 120s of the pattern portion 120 and the light emitted from the other end P1 opposite to the one end (or first point P1) of the pixel electrode 114 and incident on the point P2, A_{T} denotes an angle formed by the interface between the light rerouting layer 140 and the overcoat layer 113 and the extension line EXL1 (or the first extension line EXL1) of the bottom surface 120b of the pattern portion 120. Alternatively, the A_{T} may denote an angle formed by an inclined surface 120s of the pattern portion 120 and an extension line EXL2 (or a second extension line EXL2) of the upper surface 140a of the light rerouting layer 140.

The one end of the upper surface 113a of the overcoat layer 113 may mean a left end of the upper surface 113a of the overcoat layer 113 with reference to FIG. 6. The one end of the pixel electrode 114 may mean a left end of the pixel electrode 114 with reference to FIG. 6, and the other end of the pixel electrode 114 may mean a right end of the pixel electrode 114 with reference to FIG. 6.

On the other hand, in Equation 2, the reason for referring to the light emitted from the other end P1 of the pixel electrode 114 and incident on the point P2 is that the light emitted from the light emission area EA is incident on the second point P2 at an angle greater than the light emitted from the other end P1 of the pixel electrode 114, which is greater than the critical angle, thus the light may be totally reflected at the interface between the light rerouting layer 140 and the overcoat layer 113. Therefore, the display apparatus 100 according to an example embodiment of the present disclosure may have the other end P1 of the pixel electrode 114 (or the length L_{P} of the pixel electrode 114) set to conform to Equation 2.

According to Equation 2 above, in the display apparatus 100 according to an example embodiment of the present disclosure, the smaller the angle A_{T} formed by the interface between the light rerouting layer 140 and the overcoat layer 113 and the extension line EXL1 (or the first extension line EXL1) of the bottom surface 120b of the pattern portion 120 is, the greater the thickness D_{LO} of the light rerouting layer 140 (or the thickness T1 of the light rerouting layer 140) may be.

In other words, the thickness D_{LO} (or thickness T1) of the light rerouting layer 140 may become larger by Equation 1 (D_{LO}=D_{HO}−D_{CM}), because the D_{CM} become smaller when the A_{T} become smaller in Equation 2 (D_{CM}=(L_{CM}+Lₘ+L_{P})*tan (A_{C}+A_{T}−90°)), A larger thickness D_{LO} (or thickness T1) of the light rerouting layer 140 may mean that the light rerouting layer 140 has a thicker thickness D_{LO} (or thickness T1).

Accordingly, the display apparatus 100 according to an example embodiment of the present disclosure may be provided that the thickness D_{LO} (or thickness T1) of the light rerouting layer 140 is inversely proportional to the angle A_{T} formed by the interface (or the boundary surface) between the light rerouting layer 140 and the overcoat layer 113, and the extension line EXL1 (or the first extension line EXL1) of the bottom surface 120b of the pattern portion 120.

On the other hand, the angle A_{T} formed by the interface (or the boundary surface) between the light rerouting layer 140 and the overcoat layer 113, and the extension line EXL1 (or the first extension line EXL1) of the bottom surface 120b of the pattern portion 120, may be expressed as the angle formed by the inclined surface 120s of the pattern portion 120 with respect to the upper surface 110a of the substrate 110. Thus, the display apparatus 100 according to an example embodiment of the present disclosure may be provided that the thickness D_{LO} (or thickness T1) of the light rerouting layer 140 has an inversely proportional relationship to the angle A_{T} formed by the inclined surface 120s of the pattern portion 120 with respect to the upper surface 110a of the substrate 110.

In the above equation 2, the horizontal length (or the horizontal length in the first direction (X-axis direction)) L_{CM} from the point P2 where the upper surface 140a of the light rerouting layer 140 and the inclined surface 120s of the pattern portion 120 meet to the one end of the upper surface 113a of the overcoat layer 113 is provided to satisfy the following equation (or equation 3):

$${L}_{CM} = \frac{{D}_{CM}}{tan ( {A}_{T} )}$$

The D_{CM} is a vertical length between the upper surface 140a of the light rerouting layer 140 and the upper surface 113a of the overcoat layer 113, and the A_{T} is an angle formed by the interface between the light rerouting layer 140 and the overcoat layer 113 and the extension line EXL1 (or the first extension line EXL1) of the bottom surface 120b of the pattern portion 120.

In Equation 2 above, the angle A_{C} between the normal m to the inclined surface 120s of the pattern portion 120 and the light emitted from the other end P1 of the pixel electrode 114 and incident on point P2 is provided to satisfy the following equation (or Equation 4), in which case, the angle A_{C} is equal to the critical angle):

$${A}_{C} = a sin ( \frac{{n}_{l}}{{n}_{h}} )$$

nₕ denotes the refractive index of the overcoat layer 113, and nₗ denotes the refractive index of the light rerouting layer 140.

Meanwhile, in the above equation 1, the vertical length D_{CM} between the upper surface 140a of the light rerouting layer 140 and the upper surface 113a of the overcoat layer 113 is provided to satisfy the following equation (or equation 5):

$${D}_{CM} = \frac{tan ( {A}_{T} ) * ( {L}_{m} + {L}_{P} ) * tan ( {A}_{C} + {A}_{T} - 90 ° )}{tan ( {A}_{T} ) - tan ( {A}_{C} + {A}_{T} - 90 ° )}$$

A_{T} denotes the angle formed by the interface between the light rerouting layer 140 and the overcoat layer 113 and the extension line EXL1 (or the first extension line EXL1) of the bottom surface 120b of the pattern portion 120, and Lₘ denotes the shortest length from the one end of the upper surface 113a of the overcoat layer 113 to the one end of the pixel electrode 114, L_{P} denotes the length of the pixel electrode 114, and A_{C} denotes an angle (in some example, the critical angle) between the normal m to the inclined surface 120s of the pattern portion 120 and the light emitted from the other end P1 (or the first point P1) of the pixel electrode 114 and incident on point P2 (or the second point P2). The length L_{P} of the pixel electrode 114 may also be expressed as the length of the light emission area EA.

In Equation 5 above, an emission angle (or light emission angle) A_{C}+A_{T}−90° (or a first emission angle A_{C}+A_{T}−90°) of light, which is emitted from the other end P1 of the pixel electrode 114 and is to be incident on the second point P2, with respect to the upper surface 113a of the overcoat layer 113 is provided to satisfy a following equation (or Equation 6):

$${A}_{C} + {A}_{T} - 90 ° = 90 ° - {A}_{E}$$

The A_{E} is an emission angle (or a second emission angle) of the light, which is emitted from the other end P1 of the pixel electrode 114 and is to be incident on the second point P2, with respect to a normal to the upper surface 113a of the overcoat layer 113.

The display apparatus 100 according to an example embodiment of the present disclosure is provided with the pixel electrode 114, the overcoat layer 113, the pattern portion 120, and the light rerouting layer 140 to satisfy Equation 1 to Equation 6 above, thus light directed toward the light rerouting layer 140 (or light directed toward the second point P2) may be totally reflected from the interface (or the boundary surface) between the light rerouting layer 140 and the overcoat layer 113, as shown in FIG. 6. Light directed from the light rerouting layer 140 to below the second point P2 is incident at an angle greater than the threshold angle A_{C}, and thus may be totally reflected at the interface (or the boundary surface) of the light rerouting layer 140 and the overcoat layer 113. Accordingly, the display apparatus 100 according to an example embodiment of the present disclosure may be provided with the thickness D_{LO} of the light rerouting layer 140 (or a thickness T1 of the light rerouting layer 140) at an optimal thickness (or optimal depth) according to Equation 1 to Equation 6 above, thus the total reflection efficiency of the light rerouting layer 140 may be maximized, thereby maximizing the light extraction efficiency.

FIG. 7 is a schematic enlarged cross-sectional view illustrating a display apparatus according to another embodiment of the present disclosure, as another example of the portion A illustrated in FIG. 3.

As shown in FIG. 7, the display apparatus 100 according to another embodiment of the present disclosure is the same as the display apparatus according to FIG. 1 described above, except that the structure of the light rerouting layer 140 for the pattern portion 120 is changed. Therefore, the same drawing symbols have been given to the same configuration, and only the different configurations will be described hereinafter.

In the display apparatus according to FIG. 1 above, since the thickness T1 of the light rerouting layer 140 is thinner than the thickness T2 of the overcoat layer 113, the reflective electrode 117 may be formed to be as concave into the pattern portion 120 as a step difference between the thickness T2 of the overcoat layer 113 and the thickness T1 of the light rerouting layer 140, and thereby, the reflective portion 130 (or the first reflective portion 130a) may be disposed on the inclined surface 120s of the pattern portion 120.

Thus, the display apparatus according to FIG. 1 has the reflective portion 130 (or the first reflective portion 130a) and the light rerouting layer 140 disposed on and below the pattern portion 120, thus light directed toward the adjacent second sub-pixel SP2 among light emitted by the organic light emitting layer 116 (or the organic light emitting layer 116 of the third sub-pixel SP3) may be reflected by the reflective portion 130 (or the first reflective portion 130a) to be directed as reflected light L2 toward the emitting sub-pixel (or the third sub-pixel SP3), or may be totally reflected in the interface between the light rerouting layer 140 and the overcoat layer 113 to be directed as the total reflection light L1 in the non-light emission area NEA (e.g., the non-light emission area NEA between the second sub-pixel SP2 and the third sub-pixel SP3).

In contrast, in the case of the display apparatus according to FIG. 7, the sum angle of the angle A_{T}, which is formed by the interface (or the boundary surface) between the light rerouting layer 140 and the overcoat layer 113 and the extension line EXL1 (or the first extension line EXL1) of the bottom surface 120b of the pattern portion 120, and the angle A_{C} which is between the normal m to the inclined surface 120s of the pattern portion 120 and the light emitted from the other end P1 of the pixel electrode 114, and incident on the point P2 is greater than 0° and less than or equal to 90°, the overcoat layer 113 may be provided that the thickness D_{HO} of the overcoat layer 113 is equal to the thickness D_{LO} of the light rerouting layer 140.

According to Equation 5

$${D}_{CM} = \frac{tan ( {A}_{T} ) * ( {L}_{m} + {L}_{P} ) * tan ( {A}_{C} + {A}_{T} - 90 ° )}{tan ( {A}_{T} ) - tan ( {A}_{C} + {A}_{T} - 90 ° )}$$

when the angle A_{T} is formed by the interface (or the boundary surface) between the light rerouting layer 140 and the overcoat layer 113 and the extension line EXL1 (or the first extension line EXL1) of the bottom surface 120b of the pattern portion 120, the angle A_{C} is between the normal m to the inclined surface 120s of the pattern portion 120 and the light emitted from the other end P1 of the pixel electrode 114 and incident on the point P2, and the sum angle A_{T}+A_{C} of the angle A_{T} and the angle A_{C} is greater than 0° and less than or equal to 90°, the value of the numerator in Equation 5 has a negative value and the value of the denominator has a positive value, and thus D_{CM} may have a negative value.

Applying this to Equation 1 (D_{LO}=D_{HO}−D_{CM}), D_{LO} has a value greater than D_{HO}. D_{LO} being greater than D_{HO} means that the thickness of the light rerouting layer 140 is thicker than the thickness of the overcoat layer 113, which may mean that the light rerouting layer 140 protrudes upwardly from the upper surface 113a of the overcoat layer 113. However, since the light rerouting layer 140 is filled in the pattern portion 120, the light rerouting layer 140 is not able to substantially protrude upwardly from the upper surface 113a of the overcoat layer 113. Therefore, D_{LO} being greater than D_{HO} may mean that the thickness of the light rerouting layer 140 is equal to the thickness of the overcoat layer 113.

Thus, the display apparatus 100 according to other embodiments of the present disclosure may be provided that the thickness D_{LO} of the light rerouting layer 140 (or the thickness T1 of the light rerouting layer 140) is equal to the thickness D_{HO} of the overcoat layer 113 (or the thickness T2 of the overcoat layer 113), thus the light rerouting layer 140 fills the pattern portion 120 entirely. In this case, the thickness T1 of the light rerouting layer 140 may not differ from the thickness T2 of the overcoat layer 113, therefore a step between the light rerouting layer 140 and the overcoat layer 113 may not occur. Therefore, the display apparatus 100 according to another embodiment of the present disclosure may have the reflective portion 130 (or the reflective electrode 117) flat on the pattern portion 120, whereby a short circuit of the reflective electrode 117 may be prevented.

Furthermore, the display apparatus 100 according to other embodiments of the present disclosure is provided that the light rerouting layer 140 fills the pattern portion 120 entirely, thus light directed toward the light rerouting layer 140 among light emitted from the organic light emitting layer 116 may be reflected by the interface between the light rerouting layer 140 and the overcoat layer 113 and be directed from the non-light emission area NEA (or the light emission area EA of the emitting sub-pixel SP) as the total reflection light L1. Thus, the display apparatus 100 according to other embodiments of the present disclosure may have a better light extraction efficiency compared to a display apparatus without the pattern portion and/or the light rerouting layer.

The display apparatus according to the present disclosure is provided with a reflective portion disposed in the pattern portion formed to be concave between the plurality of the sub-pixels, and the light rerouting layer disposed below the reflective portion in the pattern portion, such that light extraction efficiency may be improved through the reflective portion and the light rerouting layer. In some examples of the present disclosure, the display apparatus may include the light rerouting layer disposed in the pattern portion without the reflective portion. For example, in such examples, the light rerouting layer may completely fill the pattern portion, for example, a thickness of the light rerouting layer may be equal to a vertical thickness between an extension line extended from a bottom surface of the pattern portion and an upper surface of the overcoat layer.

Moreover, the display apparatus according to the present disclosure may extract light even in the non-emission area through the reflective portion and the light rerouting layer, thus the display apparatus may have the same luminous efficiency or even better luminous efficiency at lower power compared to a display apparatus without the reflective portion and/or the light rerouting layer, resulting in lower overall power consumption.

Moreover, the display apparatus according to the present disclosure is provided with the reflective portion disposed on the upper side of the light rerouting layer, so that the depth at which the reflective portion, which is part of the reflective electrode, is disposed on the pattern portion is lowered, so that a short circuit of the reflective electrode may be prevented.

Moreover, the display apparatus according to the present disclosure may maximize the overall efficiency of the light rerouting layer by having the light rerouting layer disposed below the reflective portion in the pattern portion at an optimal depth, thereby maximizing the light extraction efficiency.

The effects to be obtained from the present disclosure are not limited to those mentioned above, and other effects not mentioned will be apparent to one of ordinary skill in the art from the following description.

It will be apparent to those skilled in the art that the present disclosure is not limited by the above-described example embodiments and the accompanying drawings, and that various substitutions, modifications, and variations can be made in the present disclosure without departing from the spirit or scope of the disclosures. Therefore, the above example embodiments of the present disclosure are provided for illustrative purposes and are not intended to limit the scope or technical concept of the present disclosure. Therefore, the embodiments described above are by way of example in all respects and should not be understood as limiting. The protective scope of the present disclosure should be construed based on the following claims and their equivalents, and it is intended that the present disclosure cover all modifications and variations of this disclosure that come within the scope of the claims and their equivalents.

What is claimed is:

1. A display apparatus, comprising:
a substrate including a plurality of the pixels having a plurality of the sub-pixels;
a pattern portion disposed on the substrate to be concave in a non-light emission area between the plurality of the sub-pixels;
a reflective portion disposed on the pattern portion; and
a light rerouting layer disposed below the reflective portion in the pattern portion.

2. The display apparatus of claim 1, wherein:
the pattern portion is disposed on an overcoat layer disposed on the substrate; and
a refractive index of the light rerouting layer is smaller than a refractive index of the overcoat layer.

3. The display apparatus of claim 2, wherein a thickness of the light rerouting layer is thinner than or equal to a vertical thickness between an extension line extended from a bottom surface of the pattern portion and an upper surface of the overcoat layer.

4. The display apparatus of claim 1, wherein:
each of the plurality of the sub-pixels includes a light emission area adjacent to the non-light emission area; and
the light rerouting layer is spaced apart from the light emission area.

5. The display apparatus of claim 1, wherein a width of the light rerouting layer decreases from the reflective portion toward the substrate.

6. The display apparatus of claim 1, wherein:
the pattern portion includes a bottom surface disposed in parallel to an upper surface of the substrate, and an inclined surface connected to the bottom surface to be inclined; and
the light rerouting layer contacts the entire bottom surface of the pattern portion and partially contacts the inclined surface of the pattern portion.

7. The display apparatus of claim 1, wherein:
each of the plurality of the sub-pixels includes a light emission area adjacent to the non-light emission area;
the non-light emission area includes a circuit area disposed on one side of the light emission area; and
the light rerouting layer surrounds a remainder of the light emission area except for the one side of the light emission area where the circuit area is disposed.

8. The display apparatus of claim 2, wherein:
each of the plurality of the sub-pixels includes a pixel electrode disposed on the overcoat layer; and
the light rerouting layer is spaced apart from the pixel electrode.

9. The display apparatus of claim 8, wherein each of the plurality of the sub-pixels further comprise:
an organic light emitting layer on the pixel electrode; and
a reflective electrode on the organic light emitting layer, and
wherein the reflective portion is a portion of the reflective electrode.

10. The display apparatus of claim 9, wherein:
the pattern portion includes a bottom surface disposed in parallel to an upper surface of the substrate, and an inclined surface connected to the bottom surface to be inclined; and
the reflective portion includes a first reflective portion disposed to be inclined along the inclined surface of the pattern portion and a second reflective portion connected to the first reflective portion and disposed to be flat along an upper surface of the light rerouting layer.

11. The display apparatus of claim 10, wherein in the pattern portion, the organic light emitting layer is disposed between the first reflective portion and the inclined surface of the pattern portion and between the second reflective portion and the light rerouting layer.

12. The display apparatus of claim 2, wherein:
a thickness of the light rerouting layer D_{LO} is provided to satisfy a mathematical expression below:
$${D}_{LO} = {D}_{HO} - {D}_{CM} ,$$
where D_{HO} denotes a vertical length between an extension line extended from a bottom surface of the pattern portion and an upper surface of the overcoat layer, and D_{CM} denotes a vertical length between a upper surface of the light rerouting layer and the upper surface of the overcoat layer.

13. The display apparatus of claim 12, wherein:
each of the plurality of the sub-pixels include a pixel electrode disposed on the overcoat layer; and
the vertical length D_{CM} is provided to satisfy a mathematical expression below:
$${D}_{CM} = ( {L}_{CM} + {L}_{m} + {L}_{P} ) * tan ( {A}_{C} + {A}_{T} - 90 ° ) ,$$
where:
L_{CM} denotes a horizontal length from a point where the upper surface of the light rerouting layer and an inclined surface of the pattern portion contact to an one end of the upper surface of the overcoat layer adjacent to the point;
Lₘ denotes a shortest length between the one end of the upper surface of the overcoat layer and one end of the pixel electrode adjacent to the point;
L_{P} denotes a length of the pixel electrode;
A_{C} denotes an angle between a normal to the inclined surface of the pattern portion and the light emitted from the other end opposite to the end of the pixel electrode to be incident onto the point; and
A_{T} denotes an angle between an interface between the light rerouting layer and the overcoat layer and the extension line of the bottom surface of the pattern portion.

14. The display apparatus of claim 13, wherein the horizontal length L_{CM} is provided to satisfy a mathematical expression below:
$${L}_{CM} = \frac{{D}_{CM}}{tan ( {A}_{T} )} .$$

15. The display apparatus of claim 13, wherein the critical angle A_{C} is provided to satisfy a mathematical expression below:
$${A}_{C} = a sin ( \frac{{n}_{l}}{{n}_{h}} ) ,$$
where nₕ denotes the refractive index of the overcoat layer, and nₗ denotes the refractive index of the light rerouting layer.

16. The display apparatus of claim 12, wherein:
each of the plurality of the sub-pixels include a pixel electrode disposed on the overcoat layer; and
the vertical length D_{CM} is provided to satisfy a mathematical expression below:
$${D}_{CM} = \frac{tan ( {A}_{T} ) * ( {L}_{m} + {L}_{P} ) * tan ( {A}_{C} + {A}_{T} - 90 ° )}{tan ( {A}_{T} ) - tan ( {A}_{C} + {A}_{T} - 90 ° )} ,$$
where:
A_{T} denotes an angle between an interface between the light rerouting layer and the overcoat layer and the extension line of the bottom surface of the pattern portion;
Lₘ denotes a shortest length between one end of the upper surface of the overcoat layer adjacent to a first point and one end of the pixel electrode adjacent to the first point;
L_{P} denotes a length of the pixel electrode; and
A_{C} denotes an angle between a normal to an inclined surface of the pattern portion and the light emitted from the other end opposite to the one end of the pixel electrode to be incident onto the first point, the first point is a point where the upper surface of the light rerouting layer and the inclined surface of the pattern portion contact.

17. The display apparatus of claim 16, wherein:
an emission angle A_{C}+A_{T}−90° of light, which is emitted from the other end of the pixel electrode and is to be incident onto the first point, with respect to the upper surface of the overcoat layer is provided to satisfy a mathematical expression below:
$${A}_{C} + {A}_{T} - 90 ° = 90 ° - {A}_{E} ,$$
where A_{E} denotes an emission angle of the light, which is emitted from the other end of the pixel electrode and to be incident onto the first point, with respect to a normal to the upper surface of the overcoat layer.

18. The display apparatus of claim 12, wherein the smaller an angle between an interface between the light rerouting layer and the overcoat layer and the extension line of the bottom surface of the pattern portion is, the thicker the thickness of the light rerouting layer.

19. The display apparatus of claim 15, wherein when a sum of an angle between an interface between the light rerouting layer and the overcoat layer and the extension line of the bottom surface of the pattern portion and an angle between the normal to the inclined surface of the pattern portion and the light emitted from the other end of the pixel electrode to be incident onto the point is greater than 0° and less than or equal to 90°, the thickness of the overcoat layer is equal to the thickness of the light rerouting layer.

20. The display apparatus of claim 1, wherein:
the pattern portion includes a bottom surface disposed in parallel to an upper surface of the substrate, and an inclined surface connected to the bottom surface to be inclined; and
a thickness of the light rerouting layer is inversely proportional to an angle of the inclined surface of the pattern portion with respect to an upper surface of the substrate.

21. A display apparatus comprising:
a substrate including a plurality of the pixels having a plurality of the sub-pixels;
an overcoat layer disposed on the substrate;
a pattern portion disposed in the overcoat layer to be concave in a non-light emission area between the plurality of the sub-pixels; and
a light rerouting layer disposed in the pattern portion,
wherein a refractive index of the light rerouting layer is smaller than a refractive index of the overcoat layer.

22. The display apparatus of claim 21, further comprising a plurality of color filters corresponding to the plurality of subpixels, respectively,
wherein color filters corresponding to adjacent subpixels emitting light of different colors of the plurality of subpixels among the plurality of color filters overlap with each other at a boundary portion of the adjacent subpixels.
